(19) United States
(12) Patent Application Publication
(10) Pub. No.: US 2010/0165309 A1
(43) Pub. Date: Jul. 1, 2010

(54) Deformation measuring apparatus, exposure apparatus, jig for the deformation measuring apparatus, position measuring method and device fabricating method

(75) Inventors: Takahide Kamiyama, Tokyo (JP); Norihiko Fujimaki, Fukaya-shi (JP)

Correspondence Address: OLIFF & BERRIDGE, PLC, P.O. BOX 320850, ALEXANDRIA, VA, 22320-4850, US

(73) Assignee: NIKON CORPORATION, Tokyo (JP)

(21) Appl. No.: 12/458,419

(22) Filed: Jul. 10, 2009

Related U.S. Application Data
(60) Provisional application No. 61/129,827, filed on Jul. 22, 2008.

(30) Foreign Application Priority Data
Jul. 10, 2008 (JP) 2008-180492
May 25, 2009 (JP) 2009-125201

(51) Int. Cl. G03B 27/52; G01R 29/22; G01N 25/00; G01D 5/347; G01K 5/00

(52) U.S. Cl. 355/30; 324/109; 374/6; 33/706; 355/77; 374/E05.001

(57) ABSTRACT

A piezoelectric device is provided at a base member. Regulating apparatus is provided that regulate, of deformations transmitted via the base member to the piezoelectric device, the transmission of a deformation in second directions, which intersect first directions.

### CROSS-REFERENCE TO RELATED APPLICATION

This application is a non-provisional application claiming priority to and the benefit of U.S. provisional application No. 61/129,827, filed Jul. 22, 2008, and claims priority to Japanese Patent Application No. 2008-180492, filed Jul. 10, 2008 and Japanese Patent Application No. 2009-125201, filed May 25, 2009. The entire contents of which are incorporated herein by reference.

### BACKGROUND

1. Field of the Invention

The present invention relates to a deformation measuring apparatus, an exposure apparatus, a jig for the deformation measuring apparatus, a position measuring method and a device fabricating method.

2. Description of Related Art

As a means for measuring the deformation of a body, strain gages are widely used in exposure apparatuses, which expose a substrate, such as a wafer, with, for example, the pattern of a mask.

This type of measurement calls for a strain gage that detects strain (i.e., deformation) by utilizing a property of resistors to measure the change in the electrical resistance value; with this property, when an external force is applied to a resistor made of metal and the like thereby causing the resistor to expand and contract, the electrical resistance value changes.

It is difficult, however, to measure a minute amount of strain with a strain gage that utilizes the abovementioned electrical resistance value; consequently, in such a case, a strain gage that comprises a piezoelectric device, such as that disclosed in, for example, Japanese Unexamined Patent Application Publication No. H10-160610, is used.

Nevertheless, the related art discussed above has the following problems.

With a strain gage that utilizes the abovementioned piezoelectric device, the output signal is generated such that deformation components in a plurality of directions overlap, which makes it difficult to specify a deformation component in a desired measurement direction.

Some aspects the present invention were conceived taking the above points into consideration, and it is a purpose to provide a deformation measuring apparatus, an exposure apparatus, and a jig for the deformation measuring apparatus that can measure a minute amount of deformation in a specific direction.

### SUMMARY

A first aspect of the present invention provides a deformation measuring apparatus comprising: a piezoelectric device provided to a base member; and a regulating apparatus that regulates, of deformations of a measurement target transmitted via the base member to the piezoelectric device, a transmission of a deformation in a second direction, which intersects a first direction.

Accordingly, the deformation measuring apparatus regulates deformation in the second direction that is transmitted to the piezoelectric device, which makes it possible, principally, to substantially eliminate the deformation component in the second direction as well as to measure a minute amount of the deformation component in the first directions.

A second aspect of the present invention provides an exposure apparatus that exposes a substrate with a pattern, comprising: a deformation measuring apparatus as recited above.

Accordingly, the exposure apparatus makes it possible to measure a minute amount of deformation that arises in a piece of equipment that constitutes the exposure apparatus in specific directions.

In addition, a third aspect of the present invention provides a jig for the deformation measuring apparatus comprising: a base member that supports a piezoelectric device with a support part; and a regulating apparatus that regulates, of deformations of a measurement target transmitted via the base member to the support part, a transmission of deformation in a second direction, which intersects a first direction.

Accordingly, the jig for the deformation measuring apparatus regulates deformation in the second direction that is transmitted to the piezoelectric device held by the support part, which makes it possible, principally, to substantially eliminate the deformation component in the second direction as well as to measure a minute amount of the deformation component in the first direction.

In addition, a fourth aspect of the present invention provides a deformation measuring apparatus, which uses a piezoelectric device to measure deformation that arises in a measurement target and comprises: a base member, which connects with the measurement target; a support member, which supports the piezoelectric device; and a flexure member, which connects the base member and the support member; wherein the flexure member creates, regarding deformation of the measurement target transmitted via the base member to the support member, a differential between a degree of transmission of deformation in a first direction and a degree of transmission of deformation in a second direction that intersects the first direction.

In addition, a fifth aspect of the present invention provides a jig for the deformation measuring apparatus that uses a piezoelectric device to measure deformation that arises in a measurement target and comprises: a base member, which contacts the measurement target; a support member, which supports the piezoelectric device; and a flexure member, which connects the base member and the support member; wherein the flexure member creates, regarding deformation of the measurement target transmitted via the base member to the support member, a differential between a degree of transmission of deformation in a first direction and a degree of transmission of deformation in a second direction that intersects the first direction.

A sixth aspect of the present invention provides an exposure apparatus that forms a predetermined pattern on a substrate supported by a mover, the apparatus comprising: an encoder apparatus that obtains information about a position of the mover; and a deformation measuring apparatus that is provided at least one of an encoder head and an encoder scale and that obtains information about a deformation of the one, the encoder apparatus comprising the encoder head and the encoder scale.

A seventh aspect of the present invention provides a device fabricating method that uses the above-described exposure apparatus.

An eighth aspect of the present invention provides a position measuring method of obtaining information about a position of a mover that supports a substrate onto which a predetermined pattern is formed in an exposure apparatus, the method comprising: obtaining information about a position of the mover by an encoder apparatus; and obtaining information about a deformation of at least one of an encoder head and an encoder scale, the encoder apparatus comprising the encoder head and the encoder scale.

According to some aspects of the invention, even in a case where a piezoelectric device is used, to measure a minute amount of deformation in a specific direction.

### BRIEF DESCRIPTION OF THE DRAWINGS

FIG. 1 shows a schematic configuration of a deformation measuring apparatus and a jig for the deformation measuring apparatus.

FIG. 2 shows a schematic configuration of the deformation measuring apparatus and the jig for the deformation measuring apparatus according to a second embodiment.

FIG. 3 shows a schematic configuration of the deformation measuring apparatus and the jig for the deformation measuring apparatus according to a third embodiment.

FIG. 4 is a schematic block diagram that shows one example of the exposure apparatus.

FIG. 5 is a cross sectional view that shows the vicinity of a last optical element, a liquid immersion member, and a substrate stage.

FIG. 6 is a plan view of the substrate stage and the measurement stage.

FIG. 7 is a plan view that shows the vicinity of an alignment system, a detection system, and an encoder system.

FIG. 8 is a flow chart that depicts one example of a process for fabricating a microdevice.

### DESCRIPTION OF EMBODIMENTS

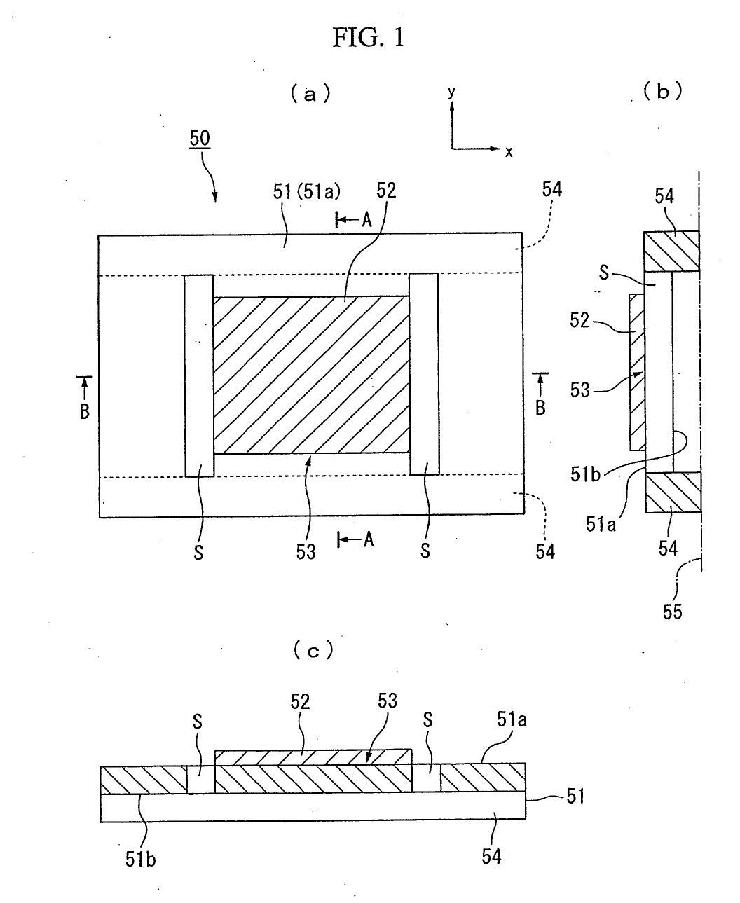

The following text explains an embodiment of a deformation measuring apparatus, an exposure apparatus, and a jig for the deformation measuring apparatus of the present invention, referencing FIG. 1 through FIG. 8.

The deformation measuring apparatus and the jig for the deformation measuring apparatus will be explained first, referencing FIG. 1.

### First Embodiment

FIG. 1 is a view that shows a schematic configuration of the deformation measuring apparatus and the jig for the deformation measuring apparatus, wherein part (a) is a plan view, part (b) is a cross sectional view taken along the A-A line, and part (c) is a cross sectional view taken along the B-B line.

Furthermore, the explanation regarding this figure defines the measurement directions of the deformation as the y directions and the directions orthogonal to (i.e., that intersect with) the measurement directions as the x directions.

A deformation measuring apparatus 50 generally comprises a base member 51 and a piezoelectric device 52. The piezoelectric device 52 comprises a lower part electrode and an upper part electrode and has a structure wherein a ferroelectric thin film (i.e., a piezoelectric layer) made of a ferroelectric material, such as lead zirconate titanate (PZT), is interposed between and held by this pair of electrodes; furthermore, the piezoelectric device 52 is formed as a rectangle whose sides are oriented along the y and x directions. Furthermore, FIG. 1 illustrates the state wherein these electrodes and the piezoelectric layer are integrated. In addition, wiring that outputs the deformation measurement result extends out from the piezoelectric device 52 (i.e., from the lower part electrode and the upper part electrode), but this is not shown in FIG. 1.

The base member 51 is formed integrally from, for example, stainless steel, aluminum, or a low thermal expansion ceramic and is rectangular in a plan view. The substantially center part of one surface 51a of the base member 51 is a rectangular support part 53, which supports the piezoelectric device 52 mounted thereon. The size of the support part 53 is substantially the same as or slightly larger than the size of the piezoelectric device 52. Projections 54 are provided to another surface 51b of the base member 51 such that they extend in the x directions along end edges in the y directions on both sides of the base member 51. Furthermore, as discussed above, the support part 53 and the projections 54 (substantially linear projections) are formed integrally, but the present invention is not limited thereto, and they may be formed separately. As shown in part (b) of FIG. 1, the deformation measuring apparatus 50 is configured such that it contacts a measurement target 55 at the joining surfaces formed by the projections 54; for example, the deformation measuring apparatus 50 is provided such that it is adhered to the measurement target 55 by, for example, an adhesive.

In addition, slit parts S (i.e., regulating apparatuses, first slit parts), which sandwich the support part 53 and extend in the y directions on both sides in the x directions of the support part 53, are formed in the base member 51 adjoining the support part 53. These slit parts S are formed such that they adjoin and are positioned in the gap between the projections 54, which are provided spaced apart in the y directions.

The base member 51 functions as a jig for the deformation measuring apparatus and can be used as the deformation measuring apparatus 50 itself by providing the piezoelectric device 52 such that it is adhered to the support part 53 by an adhesive or the like.

Continuing, the operation of the deformation measuring apparatus 50 as configured above will now be explained.

The deformation the measurement target 55 produces is transferred to the piezoelectric device 52 via the projections 54 of the base member 51.

Here, the slit parts S are formed in the base member 51 on both sides thereof in the x directions such that they sandwich the support part 53 (i.e., the piezoelectric device 52). That is, in the x directions, the slit parts S are formed in the base member 51 at both sides of the piezoelectric device 52. Therefore, the deformation in the x directions that is transferred to the base member 51 is regulated by the slit parts S, and thereby the transfer of the deformation in the x directions to the support part 53 (i.e., the piezoelectric device 52) is suppressed.

Moreover, the deformation in the y directions that is transferred to the base member 51 is transferred from the projections 54 to the piezoelectric device 52 via the support part 53.

Consequently, the piezoelectric device 52 deforms (i.e., is strained) principally in the y directions and generates a voltage in accordance with the magnitude of the deformation. For example, by measuring the voltage via the wiring, amplifying and integrating that generated voltage, and converting it to strain, it is possible to detect the amount of deformation (i.e., the amount of strain) the measurement target 55 produces.

Thus, in the present embodiment, of the deformations transferred to the piezoelectric device 52, the deformation in the x directions can be regulated by the slit parts S. As a result, it possible to easily extract and measure minute amounts of deformation in specific directions (here, the y directions) the measurement target 55 produces.

In the present embodiment, by installing one of the deformation measuring apparatuses 50 in every measurement direction with respect to the measurement target 55, it is possible to easily measure in any direction a minute amount of deformation the measurement target 55 produces.

In addition, in the present embodiment, because the projections 54, which adhere to the measurement target 55, are provided extending in the x directions, the rigidity of the base member 51 in the x directions increases and, as a result, the amount of deformation in the x directions decreases. Consequently, in the present embodiment, it is possible to reduce the deformation in the x directions that can potentially be transferred to the piezoelectric device 52. Furthermore, in the present embodiment, because the slit parts S are formed such that they fill the gap between the projections 54, it is possible to prevent deformation in the x directions from being transferred via this gap to the support part 53 and the piezoelectric device 52. Furthermore, the dimension of the piezoelectric device 52 in the Y directions may be set such that it fits as snuggly as possible between the two projections 54, which are shown in the upper and lower parts of part (a) in FIG. 1.

### Second Embodiment

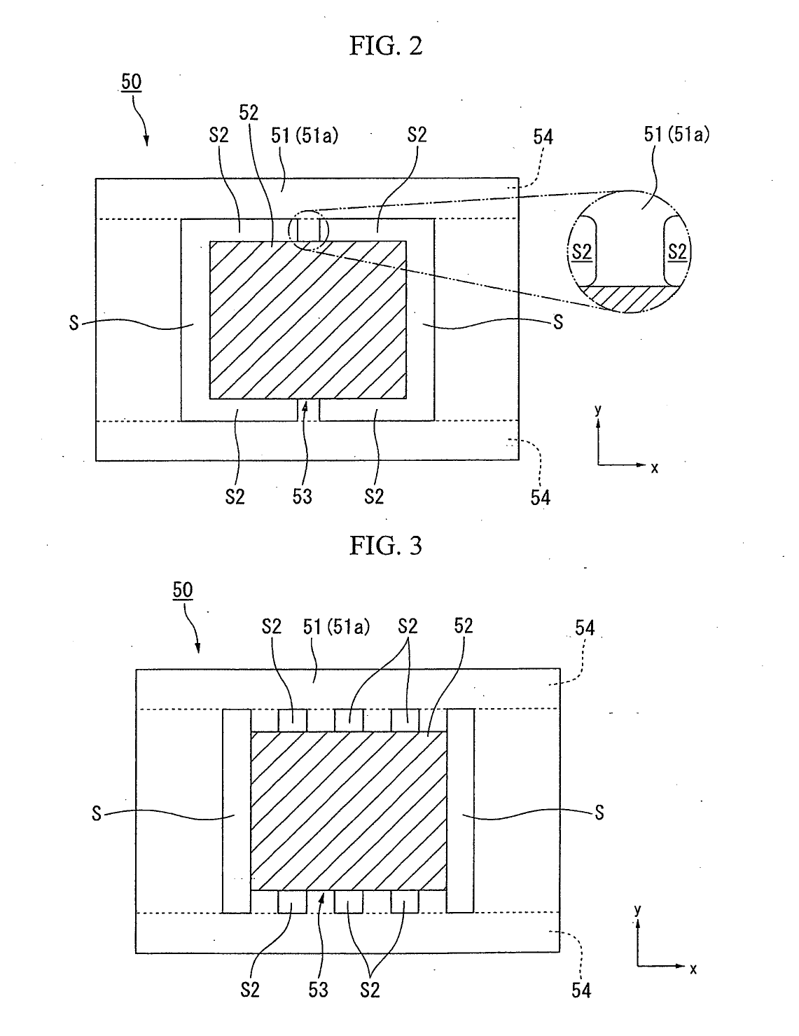

Next, the deformation measuring apparatus and the jig for the deformation measuring apparatus according to a second embodiment will be explained, referencing FIG. 2. Elements in the present figure that are identical to constituent elements in the first embodiment shown in FIG. 1 are assigned identical symbols, and the explanations thereof are therefore omitted.

In the first embodiment, the slit parts S are provided adjoining the support part 53 in the x directions; however, in the present embodiment, slit parts that adjoin the support part 53 in the y directions are also provided.

As shown in FIG. 2, second slit parts S2, which extend and are spaced apart in the x directions, are formed adjoining the support part 53 on both sides in the Y directions of the piezoelectric device 52 of the base member 51 such that they sandwich the piezoelectric device 52. One end of each of the second slit parts S2 is connected to one of the slit parts S.

Furthermore, the support part 53 and the piezoelectric device 52 are connected to the base member 51 (i.e., the projections 54) via the slit parts S and the second slit parts S2. Namely, as shown on the +y side in FIG. 2, the support part 53 and the piezoelectric device 52 are connected at the center part of the base member 51 (i.e., the projections 54) in the x directions between the second slits S2, which are disposed laterally in the figure. In addition, on the −y side in FIG. 2 as well, they are connected at the center part of the base member 51 (i.e., the projections 54) in the x directions between the second slits S2 disposed laterally in the figure. Furthermore, at other locations, the support part 53 and the piezoelectric device 52 are isolated from the base member 51 (i.e., the projections 54).

Thus, the support part 53 and the piezoelectric device 52 are connected to the base member 51 (i.e., the projections 54) by a connecting part whose length is relatively short in the x directions. The connecting part can function as, for example, a flexure part that makes the rigidity in the Y directions greater than the rigidity in the X directions; in addition, a configuration can be adopted such that displacement in the Y directions becomes more difficult and displacement in other directions becomes easier. The flexure part can be formed by, for example, performing electrical discharge machining on the base member 51 to form the slit parts S and the second slit parts S2.

Other aspects of the configuration of the present embodiment are the same as in the abovementioned first embodiment.

The deformation measuring apparatus 50 and the jig (i.e., the base member 51) in the abovementioned configuration obtain the same effects as in the first embodiment. In the embodiment, the length of the connecting part (i.e., the flexure part) in the x directions between the support part 53 and the piezoelectric device 52 on one side and the base member 51 on the other side is relatively short. Accordingly, it is possible to reduce the component of the deformation in the x directions that is included principally in the y directions deformation and transferred via the connecting part (i.e., the flexure part).

Consequently, in the present embodiment, it is possible to measure with higher accuracy the deformation in the y directions the measurement target 55 produces. Furthermore, the length of the second slit parts S2 in the x directions may simply be set such that they are shorter than the mode shown in FIG. 1 with no need to make the connecting part flexural as shown in FIG. 2. In this case, too, compared with the structure shown in FIG. 1, it is possible to measure with higher accuracy the deformation in the y directions the measurement target 55 produces. In the embodiment or in another embodiment, the length of the connecting part in the x directions can be less than the length of the support part 53 in the x directions. For example, the length of the connecting part in the x direction can be ½, ⅓, ¼, ⅕, ⅙, 1/7, ⅛, 1/9, or 1/10 of the length of the support part 53 in the x directions.

### Third Embodiment

Continuing, the deformation measuring apparatus and the jig for the deformation measuring apparatus according to a third embodiment will now be explained, referencing FIG. 3.

Constituent elements in the present figure that are identical to those in the second embodiment shown in FIG. 2 are assigned identical symbols, and the explanations thereof are therefore omitted.

In the second embodiment, the second slit parts S2 are formed such that they extend continuously in the X directions; however, in the present embodiment, they are provided such that they are dotted along the X directions.

Specifically, as shown in FIG. 3, a plurality of rectangular second slit parts S2 (here, three) are provided to the base member 51 such that they are spaced apart by a substantially constant spacing in the x directions and adjoin both sides in the y directions of the support part 53 (i.e., the piezoelectric device 52). In the embodiment, a connecting part for the support part 53 and the base member 51 are provided between two the second slit parts S2, and another connecting part is provided between one of the second slit parts S2 and the slit part S. In another embodiment, the second slit parts S2 have different shapes from each other.

Other aspects of the configuration of the present embodiment are the same as in the abovementioned second embodiment.

In the second embodiment, the length of the connecting part between the support part 53 and the base member 51 is shortened, which reduces the impact of deformation with a component in the x directions that is transferred via that connecting part; however, if the width of the connecting part is shortened, the deformation in the y directions that is transferred via the connecting part will be reduced, which will necessitate increasing the sensitivity of the piezoelectric device 52.

In the present embodiment, by disposing a plurality of the second slit parts S2 spaced apart from one another in the x directions, deformation in the y directions is transferred via the plurality of connecting parts while reducing both the width of the single connecting part and the deformation component in the x directions; therefore, it is no longer necessary to increase the sensitivity of the piezoelectric device 52.

Accordingly, the same effects as those obtained in the second embodiment are obtained in the present embodiment; additionally, it is possible to measure with even higher accuracy the deformation in the y directions the measurement target 55 produces.

### (Exposure Apparatus)

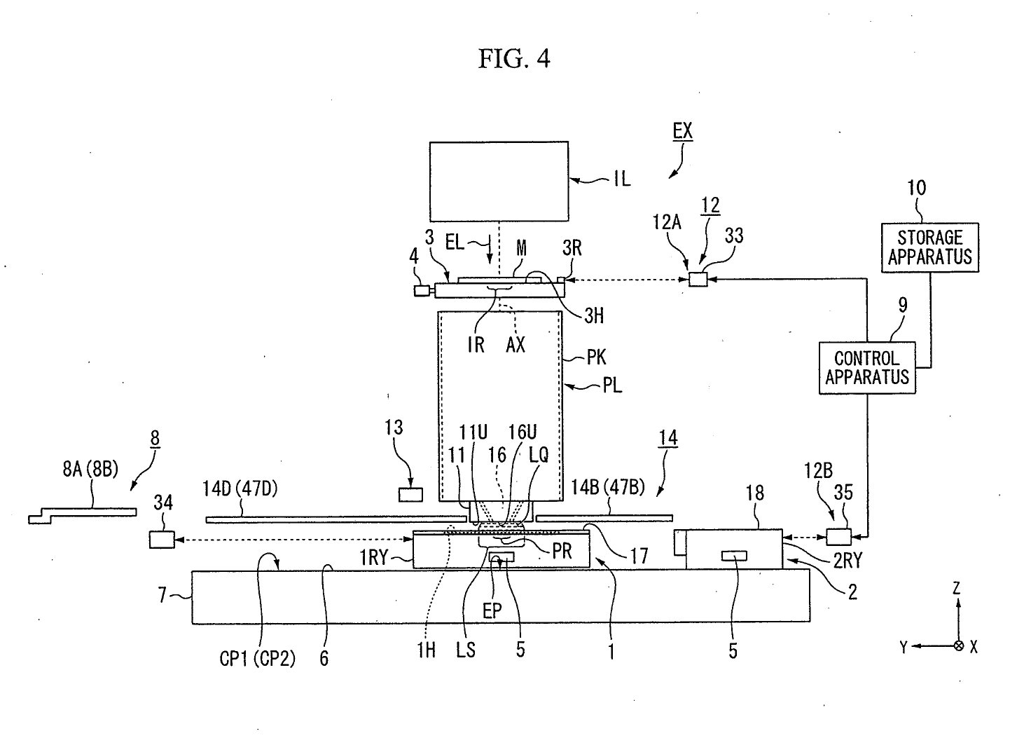

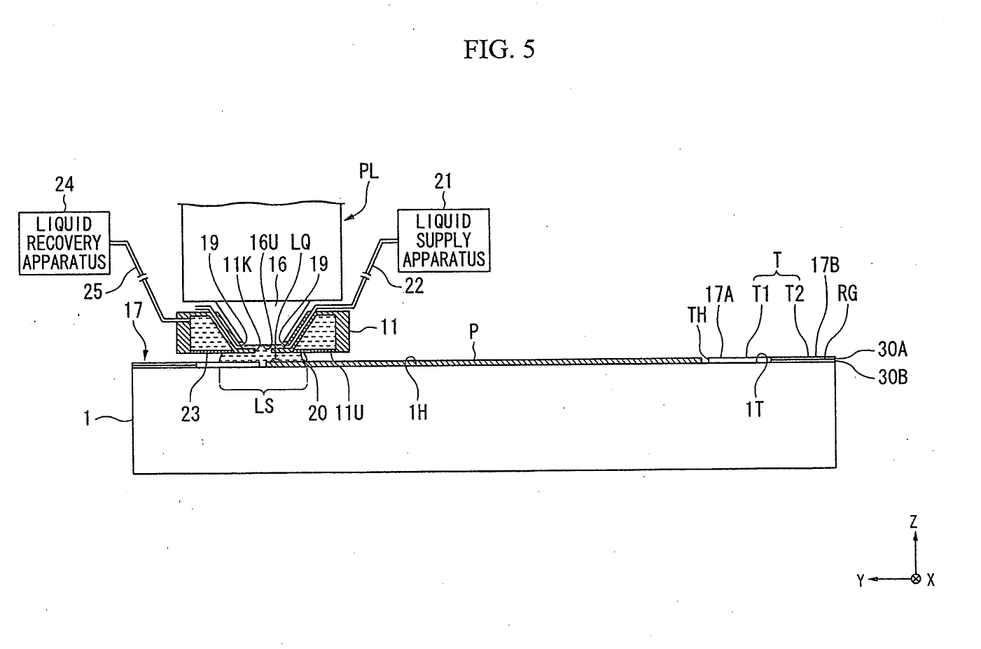

Continuing, the exposure apparatus provided with the deformation measuring apparatus 50 will now be explained, referencing FIG. 4 through FIG. 7.

The explanation below presents an example of a configuration wherein information relating to the position of, for example, a stage of the exposure apparatus and a substrate (e.g., a wafer) mounted on the stage is derived, and based on the measurement results of the deformation measuring apparatus, the information related to those derived positions is corrected. First, the configuration of the exposure apparatus will be explained, after which the correcting method wherein the deformation measuring apparatus is used will be explained. In addition, the explanation below defines an XYZ orthogonal coordinate system, and the positional relationships among members are explained referencing this system. Prescribed directions within the horizontal plane are the X axial directions, directions orthogonal to the X axial directions in the horizontal plane are the Y axial directions, and directions orthogonal to the X axial directions and the Y axial directions (i.e., the vertical directions) are the Z axial directions. In addition, the rotational (i.e., inclined) directions around the X, Y, and Z axes are the θX, θY, and θZ directions, respectively.

FIG. 4 is a schematic block diagram that shows one example of an exposure apparatus EX. The present embodiment explains an exemplary case wherein the exposure apparatus EX is an exposure apparatus that comprises: a movable substrate stage 1, which holds a substrate P; and a movable measurement stage 2, which does not hold the substrate P, whereon measuring members and the like that are capable of performing prescribed exposure related measurements are mounted, as disclosed in, for example, U.S. Pat. No. 6,897,963 and European Patent Application Publication No. 1713113.

In addition, the present embodiment explains an exemplary case wherein the exposure apparatus EX is an immersion exposure apparatus that exposes the substrate P with exposure light EL that passes through a liquid LQ, as disclosed in, for example, U.S. Patent Application Publication No. 2005/0280791 and U.S. Patent Application Publication No. 2007/0127006.

In FIG. 4, the exposure apparatus EX comprises: a movable mask stage 3, which holds a mask M; the movable substrate stage 1, which holds the substrate P; the movable measurement stage 2, which does not hold the substrate P, whereon measuring members and the like that are capable of performing prescribed exposure related measurements are mounted; a first drive system 4, which moves the mask stage 3; a second drive system 5, which moves the substrate stage 1 and the measurement stage 2; a base plate 7, which has a guide surface 6 that movably supports the substrate stage 1 and the measurement stage 2; an illumination system IL, which illuminates the mask M with the exposure light EL; a projection optical system PL, which projects an image of a pattern of the mask M illuminated by the exposure light EL to the substrate P; a transport system 8, which transports the substrate P; a control apparatus 9, which controls the operation of the entire exposure apparatus EX; and a storage apparatus 10, which is connected to the control apparatus 9 and is capable of storing various exposure related information.

In addition, the exposure apparatus EX comprises a liquid immersion member 11, which is capable of forming an immersion space LS such that at least part of the optical path of the exposure light EL is filled with the liquid LQ. The immersion space LS is a space that is filled with the liquid LQ. In the present embodiment, water (i.e., pure water) is used as the liquid LQ.

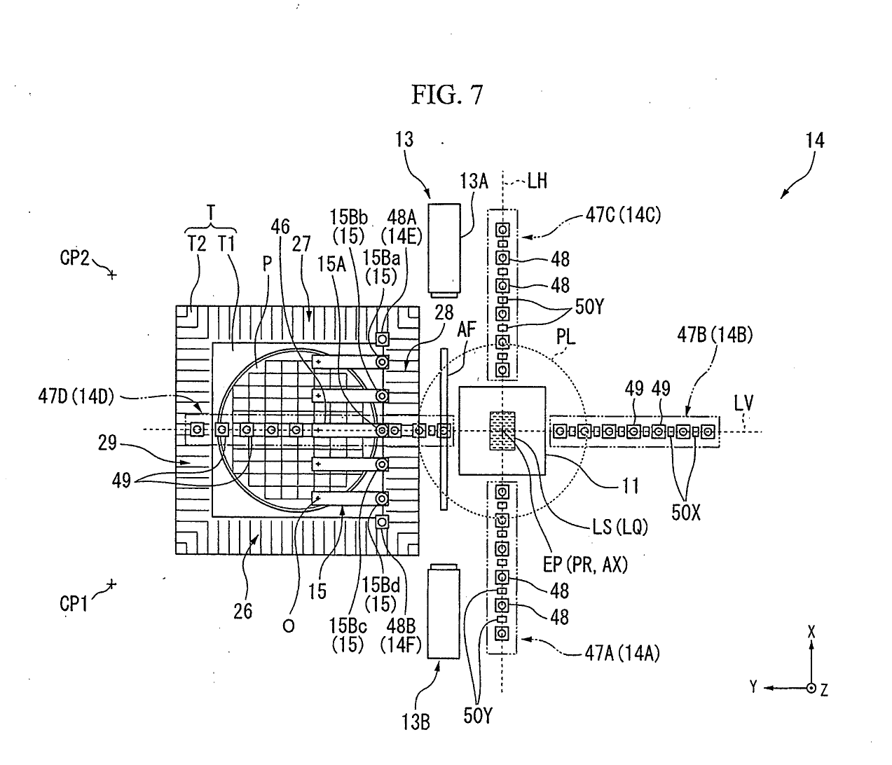

In addition, the exposure apparatus EX comprises: an interferometer system 12, which measures the positions of the mask stage 3, the substrate stage 1, and the measurement stage 2; a detection system 13 (i.e., a focus and level detection system), which detects the position of the front surface of the substrate P held by the substrate stage 1; an encoder system 14, which measures the position of the substrate stage 1; and an alignment system 15, which measures the position of the substrate P (refer to FIG. 7).

The interferometer system 12 comprises: a first interferometer unit 12A, which measures the position of the mask stage 3; and a second interferometer unit 12B, which measures the positions of the substrate stage 1 and the measurement stage 2. The detection system 13 comprises: a radiating apparatus (not shown), which emits detection light; and a light receiving apparatus (not shown), which is disposed such that it has a prescribed positional relationship with respect to the radiating apparatus and is capable of receiving the detection light. The encoder system 14 comprises: Y linear encoders 14A, 14C, 14E, 14F (refer to FIG. 7), which measure the position of the substrate stage 1 in the Y axial directions; and X linear encoders 14B, 14D (refer to FIG. 7), which measure the position of the substrate stage 1 in the X axial directions. The alignment system 15 comprises a primary alignment system 15A and a secondary alignment system 15B (refer to FIG. 7).

The substrate P is a substrate for fabricating devices. The substrate P comprises a base material (e.g., a semiconductor wafer, such as a silicon wafer) whereon a photosensitive film is formed. In the present embodiment, a transmissive mask is used as the mask M. This transmissive mask is not limited to a binary mask wherein a pattern is formed with a light shielding film, but may also include, for example, a halftone type mask or a phase shift mask of the spatial frequency modulation type. Furthermore, the mask M may alternatively be a reflective mask.

As disclosed in, for example, U.S. Patent Application Publication No. 2003/0025890, the illumination system IL comprises a light source, a luminous flux intensity uniformizing optical system that includes an optical integrator, and a blind mechanism; furthermore, the illumination system IL illuminates a prescribed illumination area IR with the exposure light EL, which has a uniform luminous flux intensity distribution. Examples of light that can be used as the exposure light EL that emerges from the illumination system IL include: deep ultraviolet (DUV) light such as a bright line (g-line, h-line, or i-line) light emitted from, for example, a mercury lamp and KrF excimer laser light (with a wavelength of 248 nm); and vacuum ultraviolet (VUV) light such as ArF excimer laser light (with a wavelength of 193 nm) and F₂ laser light (with a wavelength of 157 nm). In the present embodiment, ArF excimer laser light, which is ultraviolet light (e.g., vacuum ultraviolet light), is used as the exposure light EL.

The mask stage 3 comprises a mask holding part 3H that holds the mask M. The mask holding part 3H is capable of chucking and dechucking the mask M. In the present embodiment, the mask holding part 3H holds the mask M such that the lower surface of the mask M (i.e., its patterned surface) is substantially parallel to the XY plane. The first drive system 4 comprises actuators such as linear motors. The mask stage 3 holds the mask M and is capable of moving within the XY plane by the operation of the first drive system 4. In the present embodiment, in the state wherein the mask M is held by the mask holding part 3H, the mask stage 3 is capable of moving in three directions, namely, the X axial, Y axial, and θZ directions.

The projection optical system PL radiates the exposure light EL to the prescribed irradiation area PR (i.e., the projection area). The projection optical system PL projects with a prescribed projection magnification an image of the pattern of the mask M to at least the part of the substrate P that is disposed in the projection area PR. The projection optical system PL comprises a last optical element 16, which is capable of opposing the substrate P. The last optical element 16 has an emergent surface 16U (i.e., a lower surface) that emits the exposure light EL toward the image plane of the projection optical system PL. The exposure light EL emitted from the lower surface 16U of the last optical element 16 is radiated to the substrate P.

A lens barrel PK holds the plurality of optical elements of the projection optical system PL. Although not shown, a frame member (i.e., a lens barrel base plate), which is supported by three support posts via vibration isolating mechanisms, is provided whereon the lens barrel PK is mounted. Furthermore, as disclosed in, for example, PCT International Publication No. WO 2006/038952, the lens barrel PK of the projection optical system PL may be hung down from a support member disposed below the projection optical system PL.

The projection optical system PL of the present embodiment is a reduction system that has a projection magnification of, for example, ¼, ⅕, or ⅛, but it may be a unity magnification system or an enlargement system. In the present embodiment, an optical axis AX of the projection optical system PL is substantially parallel to the Z axis. In addition, the projection optical system PL may be a dioptric system that does not include catoptric elements, a catoptric system that does not include dioptric elements, or a catadioptric system that includes both catoptric and dioptric elements. In addition, the projection optical system PL may form either an inverted or an erect image.

The substrate stage 1 and the measurement stage 2 are each capable of moving on a guide surface 6 of a base member 7 (base plate). In the present embodiment, the guide surface 6 is substantially parallel to the XY plane. The substrate stage 1 holds the substrate P and is capable of moving along the guide surface 6 within an XY plane. The measurement stage 2 is capable of moving within the XY plane along the guide surface 6 independently of the substrate stage 1. The substrate stage 1 and the measurement stage 2 are each capable of moving to a position at which it opposes the lower surface 16U of the last optical element 16. Positions that oppose the lower surface 16U of the last optical element 16 include an irradiation position EP of the exposure light EL emitted from the lower surface 16U of the last optical element 16. Where appropriate in the explanation below, the irradiation position EP of the exposure light EL that opposes the lower surface 16U of the last optical element 16 is called the exposure position EP.

The substrate stage 1 comprises a substrate holding part 1H, which holds the substrate P. The substrate holding part 1H is capable of chucking and dechucking the substrate P. In the present embodiment, the substrate holding part 1H holds the substrate P such that the front surface (i.e., the exposure surface) of the substrate P is substantially parallel to the XY plane. The second drive system 5 comprises actuators such as linear motors. The substrate stage 1 holds the substrate P and is capable of moving within the XY plane by the operation of the second drive system 5. In the present embodiment, in the state wherein the substrate P is held by the substrate holding part 1H, the substrate stage 1 is capable of moving in six directions: the X axial, Y axial, and Z axial directions, and the θX, θY, and θZ directions.

The substrate stage 1 has an upper surface 17, which is disposed around the substrate holding part 1H. In the present embodiment, the upper surface 17 of the substrate stage 1 is flat and substantially parallel to the XY plane. The substrate stage 1 has a recessed part. The substrate holding part 1H is disposed on the inner side of the recessed part. In the present embodiment, the upper surface 17 of the substrate stage 1 and the front surface of the substrate P held by the substrate holding part 1H are disposed in substantially the same plane (i.e., flush with one another). Namely, the substrate stage 1 holds the substrate P with the substrate holding part 1H such that the upper surface 17 of the substrate stage 1 and the front surface of the substrate P are disposed in substantially the same plane (i.e., so that they are flush with one another).

Measuring instruments and the measuring members (i.e., optical components), which are capable of performing prescribed exposure related measurements, are mounted on the measurement stage 2, which does not hold the substrate P. The measurement stage 2 is capable of moving within the XY plane by the operation of the second drive system 5. In the present embodiment, the measurement stage 2 is capable of moving—in the state wherein at least some of the measuring instruments and the measuring members are mounted thereon—in six directions, namely, the X axial, Y axial, and Z axial directions, and the θX, θY, and θZ directions.

The measurement stage 2 has an upper surface 18, which is disposed around the measuring members. In the present embodiment, the upper surface 18 of the measurement stage 2 is flat and substantially parallel to the XY plane. In the present embodiment, the control apparatus 9 can adjust the positional relationship between the substrate stage 1 and the measurement stage 2 by operating the second drive system 5 such that the upper surface 17 of the substrate stage 1 and the upper surface 18 of the measurement stage 2 are disposed substantially within the same plane (i.e., so that they are flush with one another).

The transport system 8 is capable of transporting the substrate P. In the present embodiment, the transport system 8 comprises a transport member 8A, which is capable of loading the unexposed substrate P onto the substrate holding part 1H, and a transport member 8B, which is capable of unloading the exposed substrate P from the substrate holding part 1H.

When the substrate P is loaded onto the substrate holding part 1H, the control apparatus 9 moves the substrate stage 1 to a first substrate exchange position CP1 (i.e., a loading position), which is different from the exposure position EP. In addition, when the substrate P is unloaded from the substrate holding part 1H, the control apparatus 9 moves the substrate stage 1 to a second substrate exchange position CP2 (i.e., an unloading position), which is different from the exposure position EP.

The substrate stage 1 is capable of moving within a prescribed area of the guide surface 6 that includes the exposure position EP and the first and second substrate exchange positions CP1, CP2. The transport system 8 is capable of performing both a loading operation that loads the substrate P onto the substrate holding part 1H of the substrate stage 1 when the substrate stage 1 has moved to the first substrate exchange position CP1 and an unloading operation that unloads the substrate P from the substrate holding part 1H of the substrate stage 1 when the substrate stage 1 has moved to the second substrate exchange position CP2. The control apparatus 9 is capable of performing a substrate exchange operation, which includes both the unloading operation that uses the transport system 8 to unload the exposed substrate P from the substrate stage 1 (i.e., the substrate holding part 1H) when it has moved to the second substrate exchange position CP2, and the loading operation that loads the unexposed substrate P to be exposed next onto the substrate stage 1 (i.e., the substrate holding part 1H) when it has moved to the first substrate exchange position CP1.

The liquid immersion member 11 is capable of forming the immersion space LS with the liquid LQ such that at least part of the optical path of the exposure light EL is filled with the liquid LQ. In the present embodiment, the liquid immersion member 11 is disposed in the vicinity of the last optical element 16. The liquid immersion member 11 has a lower surface 11U that is capable of opposing the object disposed at the exposure position EP. In the present embodiment, the liquid immersion member 11 is capable of forming the immersion space LS with the liquid LQ between the object and the liquid immersion member 11 such that the optical path of the exposure light EL between the last optical element 16 and the object disposed at the exposure position EP is filled with the liquid LQ. In the present embodiment, the immersion space LS is formed with the liquid LQ held between the liquid immersion member 11 and the lower surface 16U of the last optical element 16 on one side and the object that opposes the last optical element 16 and the liquid immersion member 11 on the other.

The object that is capable of opposing the last optical element 16 and the liquid immersion member 11 includes an object that is capable of moving on the emergent side of the last optical element 16 (i.e., on the image plane side of the projection optical system PL). In the present embodiment, the movable objects on the emergent side of the last optical element 16 include either the substrate stage 1 or the measurement stage 2, or both. In addition, the object includes the substrate P held by the substrate stage 1. In addition, the object includes the various measuring members (i.e., the optical components) mounted on the measurement stage 2.

When the substrate P, which is held by the substrate stage 1, is to be exposed, the substrate P is disposed at the exposure position EP such that it opposes the last optical element 16 and the liquid immersion member 11. In the present exposure apparatus, the immersion space LS is formed, at least at the time the substrate P is to be exposed, by holding the liquid LQ between the last optical element 16 and the liquid immersion member 11 on one side and the substrate P on the other side such that the optical path of the exposure light EL that emerges from the lower surface 16U of the last optical element 16 is filled with the liquid LQ.

In the present embodiment, the immersion space LS is formed such that part of the area of the front surface of the substrate P that includes the projection area PR of the projection optical system PL is covered with the liquid LQ. An interface (i.e., a meniscus or an edge) of the liquid LQ is formed between the lower surface 11U of the liquid immersion member 11 and the front surface of the substrate P. Namely, the exposure apparatus EX of the present embodiment adopts a local liquid immersion system.

In addition, when a measurement is performed using the measurement stage 2, the measuring members mounted on the measurement stage 2 are disposed at the exposure position EP such that they oppose the last optical element 16 and the liquid immersion member 11. When a measurement is performed using at least the measuring members, the liquid immersion member 11 is capable of forming the immersion space LS by filling the optical path of the exposure light EL between the last optical element 16 and the substrate P with the liquid LQ. When measurement is performed using the measuring members, the immersion space LS is formed by holding the liquid LQ between the last optical element 16 and the liquid immersion member 11 on one side and the measuring members on the other side such that the optical path of the exposure light EL that emerges from the lower surface 16U of the last optical element 16 is filled with the liquid LQ.

FIG. 5 is a cross sectional view that shows the vicinity of the substrate stage 1, which is disposed at the exposure position EP, the last optical element 16, and the liquid immersion member 11. The liquid immersion member 11 has an opening 11K at a position that opposes the lower surface 16U of the last optical element 16. The liquid immersion member 11 comprises supply ports 19, which are capable of supplying the liquid LQ, and a recovery port 20, which is capable of recovering the liquid LQ.

The supply ports 19 are capable of supplying, into the optical path of the exposure light EL, the liquid LQ for forming the immersion space LS. The supply ports 19 are disposed in the vicinity of the optical path of the exposure light EL at prescribed positions of the liquid immersion member 11 that oppose the optical path. In addition, the exposure apparatus EX comprises a liquid supply apparatus 21. The liquid supply apparatus 21 is capable of feeding the liquid LQ, which is pure and temperature adjusted. The supply ports 19 are connected to the liquid supply apparatus 21 via passageways 22. The liquid LQ that is fed from the liquid supply apparatus 21 is supplied to each of the supply ports 19 through the corresponding passageway 22. The supply ports 19 supply the liquid LQ from the liquid supply apparatus 21 to the optical path of the exposure light EL. In addition, in the present embodiment, the liquid supply apparatus 21 comprises a liquid supply amount adjusting apparatus that includes a valve mechanism, a mass flow controller, and the like. The liquid supply apparatus 21 is capable of using the liquid supply amount adjusting apparatus to adjust the amount of liquid supplied per unit of time to the supply port 19.

The recovery port 20 is capable of recovering at least part of the liquid LQ on the object that opposes the lower surface 11U of the liquid immersion member 11. The recovery port 20 is disposed at a prescribed position of the liquid immersion member 11 at which it opposes the front surface of the object. A plate shaped porous member 23, which has a plurality of holes (i.e., openings or pores), is disposed in the recovery port 20. Furthermore, a mesh filter, which is a porous member wherein numerous small holes are formed as a mesh, may be disposed in the recovery port 20. In the present embodiment, at least part of the lower surface 11U of the liquid immersion member 11 comprises the lower surface of the porous member 23. In addition, the exposure apparatus EX comprises a liquid recovery apparatus 24, which is capable of recovering the liquid LQ. The liquid recovery apparatus 24 comprises a vacuum system and is capable of recovering the liquid LQ via suctioning. The recovery port 20 is connected to the liquid supply apparatus 24 via a passageway 25. The liquid LQ recovered via the recovery port 20 is recovered by the liquid recovery apparatus 24 through the passageway 25. In addition, in the present embodiment, the liquid recovery apparatus 24 comprises a liquid recovery amount adjusting apparatus, which includes a valve mechanism, a mass flow controller, and the like. The liquid recovery apparatus 24 is capable of using the liquid recovery amount adjusting apparatus to adjust the amount of liquid recovered per unit of time via the recovery port 20.

In the present embodiment, the control apparatus 9 is capable of forming the immersion space LS with the liquid LQ between the last optical element 16 and the liquid immersion member 11 on the one side and the object that opposes such on the other side by performing a liquid recovery operation, wherein the recovery port 20 is used, in parallel with a liquid supply operation, wherein the supply ports 19 are used.

The substrate stage 1 comprises the substrate holding part 1H, which is capable of chucking and dechucking the substrate P. In the present embodiment, the substrate holding part 1H comprises a so-called pin chuck mechanism. The substrate holding part 1H opposes and holds a rear surface of the substrate P. The upper surface 17 of the substrate stage 1 is disposed around the substrate holding part 1H. The substrate holding part 1H holds the substrate P such that the front surface of the substrate P is substantially parallel to the XY plane. In the present embodiment, the front surface of the substrate P held by the substrate holding part 1H and the upper surface 17 of the substrate stage 1 are substantially parallel. In addition, in the present embodiment, the front surface of the substrate P held by the substrate holding part 1H and the upper surface 17 of the substrate stage 1 are disposed substantially within the same plane (i.e., they are substantially flush with one another).

In the present embodiment, the substrate stage 1 comprises a plate member T, which is disposed around the substrate P held by the substrate holding part 1H. In the present embodiment, the substrate stage 1 is capable of chucking and dechucking the plate member T. In the present embodiment, the substrate stage 1 comprises a plate member holding part 1T, which is capable of chucking and dechucking the plate member T. In the present embodiment, the plate member holding part 1T comprises a so-called pin chuck mechanism. The plate member holding part 1T is disposed around the substrate holding part 1H. The plate member holding part 1T opposes and holds the lower surface of the plate member T.

The plate member T has an opening TH in which the substrate P is capable of being disposed. The plate member T held by the plate member holding part 1T is disposed around the substrate P, which is held by the substrate holding part 1H. In the present embodiment, the inner surface of the opening TH of the plate member T held by the plate member holding part 1T and the outer surface of the substrate P held by the substrate holding part 1H are disposed such that they oppose one another with a prescribed gap interposed therebetween. The plate member holding part 1T holds the plate member T such that the upper surface of the plate member T is substantially parallel to the XY plane. In the present embodiment, the front surface of the substrate P held by the substrate holding part 1H and the upper surface of the plate member T held by the plate member holding part 1T are substantially parallel. In addition, in the present embodiment, the front surface of the substrate P held by the substrate holding part 1H and the upper surface of the plate member T held by the plate member holding part 1T are disposed substantially within the same plane (i.e., they are substantially flush with one another).

Namely, in the present embodiment, the upper surface 17 of the substrate stage 1 includes at least part of the upper surface of the plate member T held by the plate member holding part 1T.

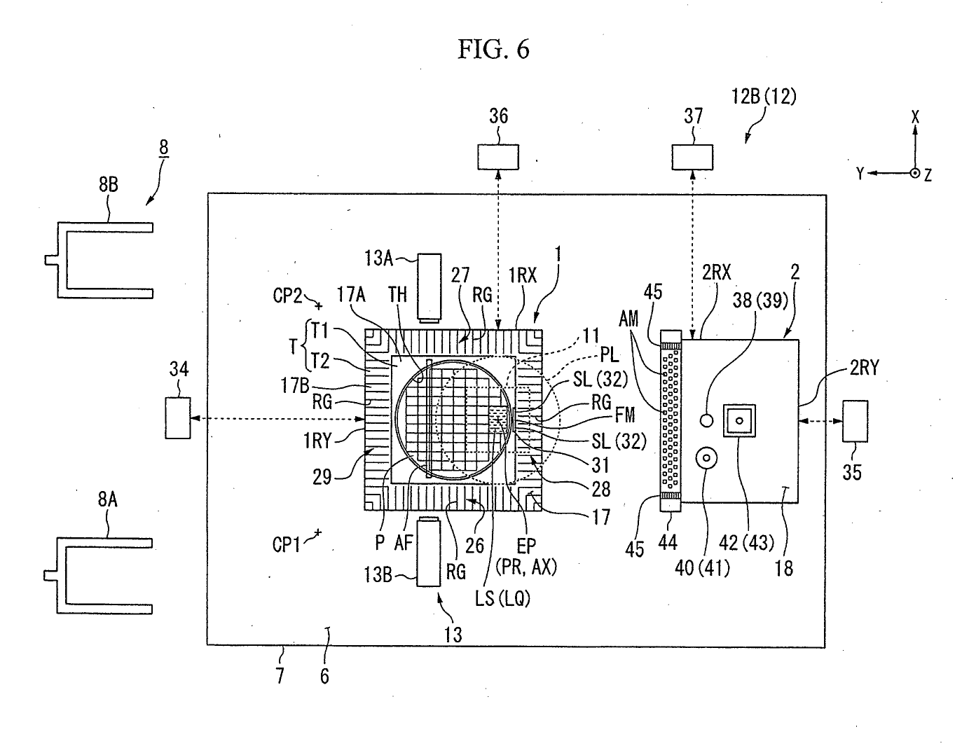

FIG. 6 is a plan view from above of the substrate stage 1 and the measurement stage 2. As shown in FIG. 6, in the present embodiment, the external shape (i.e., the contour) of the plate member T within the XY plane is rectangular. The opening TH of the plate member T, wherein the substrate P can be disposed, is circular.

In the present embodiment, the plate member T comprises a first plate T1, which has the opening TH, and a second plate T2, which is disposed around the first plate. T1. The external shape (i.e., the contour) of both the first plate T1 and the second plate T2 within the XY plane is rectangular. In addition, the opening of the second plate T2 wherein the first plate T1 is disposed is rectangular. The shape of the opening of the second plate T2 is the same as the external shape of the first plate T1.

In the present embodiment, a scale member that comprises gratings RG is disposed on the substrate stage 1. The scale member is disposed around the substrate holding part 1H. In the present embodiment, the scale member forms at least part of the upper surface 17 of the substrate stage 1. In the present embodiment, the second plate T2 functions as the scale member that comprises the gratings RG. Where appropriate in the explanation below, the second plate T2 is called the scale member T2.

In the present embodiment, the upper surface of the scale member T2 is liquid repellent with respect to the liquid LQ. The upper surface of the scale member T2 is substantially flush with the front surface of the substrate P held by the substrate holding part 1H. The substrate stage 1 holds the substrate P such that the upper surface of the scale member T2 and the front surface of the substrate P are disposed within substantially the same plane. The scale member T2 is disposed such that its upper surface lies substantially within the same plane as the first plate T1 of the substrate stage 1 and the front surface of the substrate P.

The scale member T2 comprises: Y scales 26, 27, which are for measuring the position of the substrate stage 1 in the Y axial directions; and X scales 28, 29, which are for measuring the position of the substrate stage 1 in the X axial directions. The Y scale 26 is disposed on the −X side of the opening TH, and the Y scale 27 is disposed on the +X side of the opening TH. The X scale 28 is disposed on the −Y side of the opening TH, and the X scale 29 is disposed on the +Y side of the opening TH.

Each of the Y scales 26, 27 comprises multiple gratings RG (i.e., grating lines), the longitudinal directions of which are oriented in the X axial directions, that are disposed such that they have a prescribed pitch in the Y axial directions. Namely, the Y scales 26, 27 comprise one dimensional gratings, wherein the directions of periodicity are oriented in the Y axial directions.

Each of the X scales 28, 29 comprises multiple gratings RG (i.e., grating lines), the longitudinal directions of which are oriented in the Y axial directions, that are disposed such that they have a prescribed pitch in the X axial directions. Namely, the X scales 28, 29 comprise one dimensional gratings, wherein the directions of periodicity are oriented in the X axial directions.

In the present embodiment, the gratings RG are diffraction gratings. Namely, in the present embodiment, the Y scales 26, 27 comprise diffraction gratings RG wherein the directions of periodicity are oriented in the Y axial directions, and the X scales 28, 29 comprise diffraction gratings RG wherein the directions of periodicity are oriented in the X axial directions.

In addition, in the present embodiment, the Y scales 26, 27 are reflective scales, wherein reflective gratings (i.e., reflective diffraction gratings) are formed such that their directions of periodicity are oriented in the Y axial directions. The X scales 28, 29 are also reflective scales, wherein reflective gratings (i.e., reflective diffraction gratings) are formed such that their directions of periodicity are oriented in the X axial directions.

Furthermore, for the sake of illustrative convenience, in FIG. 6 the diffraction gratings RG are shown with pitches that are markedly larger than the actual pitches. The same applies to other drawings as well.

As shown in FIG. 5 and the like, the scale member T2 comprises two plate shaped members 30A, 30B, which are adhered to one another. The plate shaped member 30A is disposed on the upper side (i.e., the +Z side) of the plate shaped member 30B. The diffraction gratings RG are provided to the upper surface (i.e., the +Z side surface) of the plate shaped member 30B, which is on the lower side. The plate shaped member 30A, which is on the upper side, covers the upper surface of the plate shaped member 30B on the lower side. Namely, the plate shaped member 30A on the upper side covers the diffraction gratings RG that are disposed on the upper surface of the plate shaped member 30B on the lower side. Thereby, the diffraction gratings RG are prevented from being degraded, damaged, and the like.

The upper surface 17 of the plate member T includes a first liquid repellent area 17A, which is disposed around the opening TH, and a second liquid repellent area 17B, which is disposed around the first liquid repellent area 17A. The external shape (i.e., the contour) of the first liquid repellent area 17A is rectangular. The external shape (i.e., the contour) of the second liquid repellent area 17B is also rectangular. In the present embodiment, the upper surface of the first plate T1 is the first liquid repellent area 17A, and the upper surface of the scale member T2 (i.e., the second plate) is the second liquid repellent area 17B. When, for example, the exposure operation is performed on the substrate P, the first liquid repellent area 17A contacts the liquid LQ in the immersion space LS (i.e., the immersion area) that overflows from the front surface of the substrate P.

The interferometer system 12 measures within the XY plane the positions of the mask stage 3, the substrate stage 1, and the measurement stage 2. The interferometer system 12 comprises: the first interferometer unit 12A, which measures the position of the mask stage 3 within the XY plane; and the second interferometer unit 12B, which measures the positions of the substrate stage 1 and the measurement stage 2 within the XY plane.

As shown in FIG. 4, the first interferometer unit 12A comprises a laser interferometer 33. The first interferometer unit 12A radiates measurement light from the laser interferometer 33 to a measurement surface 3R of the mask stage 3, and uses the measurement light that travels via that measurement surface 3R to measure the position of the mask stage 3 (i.e., the mask M) in the X axial, Y axial, and θZ directions.

As shown in FIG. 4 and FIG. 6, the second interferometer unit 12B comprises laser interferometers 34, 35, 36, 37. The second interferometer unit 12B radiates measurement lights from the laser interferometers 34, 36 to measurement surfaces 1RY, 1RX of the substrate stage 1, and uses the measurement lights that travel via those measurement surfaces 1RY, 1RX to measure the position of the substrate stage 1 (i.e., the substrate P) in the X axial, Y axial, and θZ directions. In addition, the second interferometer unit 12B radiates measurement lights from the laser interferometers 35, 37 to measurement surfaces 2RY, 2RX of the measurement stage 2, and uses the measurement lights that travel via those measurement surfaces 2RY, 2RX to measure the position of the measurement stage 2 in the X axial, Y axial, and θZ directions.

Next, the measurement stage 2 will be explained. The measurement stage 2 comprises a plurality of measuring instruments and measuring members (i.e., optical components) for performing various exposure related measurements. A first measuring member 38, wherein an opening pattern is formed through which the exposure light EL can be transmitted, is provided at a prescribed position on the upper surface 18 of the measurement stage 2. The first measuring member 38 constitutes part of an aerial image measuring system 39, which can measure an aerial image formed by the projection optical system PL, as disclosed in, for example, U.S. Patent Application Publication No. 2002/0041377. The aerial image measuring system 39 comprises the first measuring member 38 and a light receiving device that receives the exposure light EL via the opening pattern of the first measuring member 38. The control apparatus 9 radiates the exposure light EL to the first measuring member 38 and, using the light receiving device to receive the exposure light EL that passes through the opening pattern of the first measuring member 38, measures the image forming characteristics of the projection optical system PL.

In addition, a second measuring member 40, wherein a transmissive pattern is formed through which the exposure light EL can be transmitted, is provided at a prescribed position on the upper surface 18 of the measurement stage 2. The second measuring member 40 comprises part of a wavefront aberration measuring system 41, which is capable of measuring the wavefront aberration of the projection optical system PL, as disclosed in, for example, European Patent Application Publication No. 1079223. The wavefront aberration measuring system 41 comprises the second measuring member 40 and a light receiving device that receives the exposure light EL that travels through the opening pattern of the second measuring member 40. The control apparatus 9 radiates the exposure light EL to the second measuring member 40 and, using the light receiving device to receive the exposure light EL that travels through the opening pattern of the second measuring member 40, measures the wavefront aberration of the projection optical system PL.

In addition, a third measuring member 42, wherein a transmissive pattern is formed through which the exposure light EL can be transmitted, is provided at a prescribed position on the upper surface 18 of the measurement stage 2. The third measuring member 42 constitutes part of a luminous flux intensity nonuniformity measuring system 43 that can measure the nonuniformity of the luminous flux intensity of the exposure light EL, as disclosed in, for example, U.S. Pat. No. 4,465,368. The luminous flux intensity nonuniformity measuring system 43 comprises the third measuring member 42 and a light receiving device, which receives the exposure light EL that travels through the opening pattern of the third measuring member 42. The control apparatus 9 measures the nonuniformity of the luminous flux intensity of the exposure light EL by radiating the exposure light EL to the third measuring member 42 and using the light receiving device to receive the exposure light EL that travels through the opening pattern of the third measuring member 42.

In the present embodiment, a fiducial member 44 is disposed on the +Y side surface of the measurement stage 2. In the present embodiment, the fiducial member 44 is a rectangular parallelepiped called a fiducial bar (FD bar) or a confidential bar (CD bar) whose length is in the X axial directions. The fiducial member 44 is supported kinematically on the measurement stage 2 by a fully kinematic mount structure.

The fiducial member 44 functions as a standard (i.e., a measurement reference). The fiducial member 44 is formed from, for example, an optical glass member or a ceramic member that has a low coefficient of thermal expansion. The upper surface (i.e., the front surface or the +Z side surface) of the fiducial member 44 has a high degree of flatness and can function as a reference plane.

Reference gratings 45, whose directions of periodicity are oriented in the Y axial directions, are formed in the vicinity of the +X side end part and in the vicinity of the −X side end part of the fiducial member 44. Each of the reference gratings 45 comprises a diffraction grating. The reference gratings 45 are disposed spaced apart by a prescribed distance in the X axial directions. The reference gratings 45 are disposed symmetrically with respect to the center of the fiducial member 44 in the X axial directions. In addition, as shown in FIG. 6, a plurality of fiducial marks AM is formed on the upper surface of the fiducial member 44.

In addition, in the present embodiment, the upper surface of the fiducial member 44 and the upper surface 18 of the measurement stage 2 are liquid repellent with respect to the liquid LQ. In the present embodiment, a film of material that includes, for example, fluorine is formed on the upper surface of the fiducial member 44 and the upper surface 18 of the measurement stage 2. In addition, the upper surfaces of the measuring members 38, 40, 42 are also liquid repellent with respect to the liquid LQ.

The alignment system 15 will now be explained, referencing FIG. 7. FIG. 7 is a plan view that shows the vicinity of the alignment system 15, the detection system 13, and the encoder system 14. Furthermore, in FIG. 7, the measurement stage is omitted.

The alignment system 15 comprises the primary alignment system 15A and the secondary alignment system 15B, which detect the position of the substrate P. The primary alignment system 15A has a center of detection (i.e., a detection reference) on a straight line LV that is parallel to the Y axis and passes through the optical axis AX of the projection optical system PL. In the present embodiment, the center of detection of the primary alignment system 15A is disposed on the +Y side of the optical axis AX of the projection optical system PL. The center of detection of the primary alignment system 15A and the optical axis AX of the projection optical system PL are spaced apart by a prescribed distance. The primary alignment system 15A is supported by a support member 46.

In the present embodiment, the secondary alignment system 15B comprises four secondary alignment systems 15Ba, 15Bb, 15Bc, 15Bd. The secondary alignment systems 15Ba, 15Bb are disposed on the +X side of the primary alignment system 15A, and the secondary alignment systems 15Bc, 15Bd are disposed on the −X side of the primary alignment system 15A. The centers of detection (i.e., the detection references) of the secondary alignment systems 15Ba, 15Bb and the centers of detection (i.e., the detection references) of the secondary alignment systems 15Bc, 15Bd are disposed substantially symmetrically with respect to the straight line LV. Each of the secondary alignment systems 15Ba-15Bd is capable of rotating within the XY plane around a center of rotation O. The position in the X axial directions of each of the secondary alignment systems 15Ba-15Bd is adjusted by rotating the relevant secondary alignment system.

In the present embodiment, the primary alignment system 15A and the four secondary alignment systems 15Ba-15Bd each employ a field image alignment (FIA) alignment system, as disclosed in, for example, U.S. Pat. No. 5,493,403, that irradiates a target mark (e.g., an alignment mark on the substrate P) with broadband detection light that does not photosensitize the photosensitive film on the substrate P, uses an image capturing device (e.g., a CCD) to capture an image of an index (i.e., an index mark on an index plate provided in each alignment system) and an image of the target mark that is formed on a light receiving surface by the light reflected from that target mark, and measures the position of the mark by image processing these captured image signals. The captured image signals of the primary alignment system 15A and the four secondary alignment systems 15Ba-15Bd are output to the control apparatus 9.

The following text explains the encoder system 14, referencing FIG. 7. In the present embodiment, the encoder system 14 is capable of measuring the position of the substrate stage 1 within the XY plane. The encoder system 14 uses the scale member T2 to measure the position of the substrate stage 1 within the XY plane. The encoder system 14 comprises: the Y linear encoders 14A, 14C, which measure the position of the substrate stage 1 in the Y axial directions; and the X linear encoders 14B, 14D, which measure the position of the substrate stage 1 in the X axial directions.

The Y linear encoder 14A comprises a head unit 47A, which is capable of opposing the scale member T2. The X linear encoder 14B comprises a head unit 47B, which is capable of opposing the scale member T2. The Y linear encoder 14C comprises a head unit 47C, which is capable of opposing the scale member T2. The X linear encoder 14D comprises a head unit 47D, which is capable of opposing the scale member T2. The four head units 47A-47D are disposed such that they surround the liquid immersion member 11.

The head unit 47A is disposed on the −X side of the projection optical system PL. The head unit 47C is disposed on the +X side of the projection optical system PL. Both of the head units 47A, 47C are long in the X axial directions. The head unit 47A and the head unit 47C are disposed symmetrically with respect to the optical axis AX of the projection optical system PL. Within the XY plane, the distance between the head unit 47A and the optical axis AX of the projection optical system PL is substantially the same that between the head unit 47C and the optical axis AX of the projection optical system PL.

The head unit 47B is disposed on the −Y side of the projection optical system PL. The head unit 47D is disposed on the +Y side of the projection optical system PL. Both of the head units 47B, 47D are long in the Y axial directions. The head unit 47B and the head unit 47D are disposed symmetrically with respect to the optical axis AX of the projection optical system PL. Within the XY plane, the distance between the head unit 47B and the optical axis AX of the projection optical system PL is substantially the same as that between the head unit 47D and the optical axis AX of the projection optical system PL.

The head unit 47A comprises multiple Y heads 48 (in the present embodiment, six), which are disposed along the X axial directions. The Y heads 48 of the head unit 47A are disposed at prescribed intervals along a straight line LH, which passes through the optical axis AX of the projection optical system PL and is parallel to the X axis.

The head unit 47C comprises multiple Y heads 48 (in the present embodiment, six), which are disposed along the X axial directions. The Y heads 48 of the head unit 47C are disposed at prescribed intervals along the straight line LH, which passes through the optical axis AX of the projection optical system PL and is parallel to the X axis.

Each of the Y heads 48 of the head units 47A, 47C are capable of opposing the scale member T2.

The head unit 47A uses the Y heads 48 and the Y scale 26 of the scale member T2 to measure the position of the substrate stage 1 in the Y axial directions. The head unit 47A comprises the plurality of Y heads 48 (here, six) and constitutes the so-called multilens (i.e., six-lens) Y linear encoder 14A.

The head unit 47C uses the Y heads 48 and the Y scale 27 of the scale member T2 to measure the position of the substrate stage 1 in the Y axial directions. The head unit 47C comprises the plurality of Y heads 48 (here, six) and constitutes the so-called multilens (i.e., six-lens) Y linear encoder 14C.

In the head unit 47A, the spacing in the X axial directions between adjacent Y heads 48 (i.e., between the measurement lights of adjacent Y heads 48) is smaller than the width in the X axial directions of each of the Y scales 26, 27 (i.e., the length of each of the diffraction gratings RG). Likewise, in the head unit 47C, the spacing in the X axial directions between adjacent Y heads 48 (i.e., between the measurement lights of adjacent Y heads 48) is smaller than the width in the X axial directions of each of the Y scales 26, 27 (i.e., the length of each of the diffraction gratings RG).

The head unit 47B comprises multiple X heads 49 (in the present embodiment, seven), which are disposed along the Y axial directions. The X heads 49 of the head unit 47B are disposed at prescribed intervals along the straight line LV, which passes through the optical axis AX of the projection optical system PL and is parallel to the Y axis.

The head unit 47D comprises multiple X heads 49 (in the present embodiment, eleven), which are disposed along the Y axial directions. The X heads 49 of the head unit 47D are disposed at prescribed intervals along the straight line LV, which passes through the optical axis AX of the projection optical system PL and is parallel to the Y axis.

Each of the X heads 49 of the head units 47B, 47D are capable of opposing the scale member T2.

Furthermore, in FIG. 7, those X heads 49 of the plurality of X heads 49 of the head unit 47D that are overlapped by the primary alignment system 15A are not shown.

The head unit 47B uses the X heads 49 and the X scale 28 of the scale member T2 to measure the position of the substrate stage 1 in the X axial directions. The head unit 47B comprises a plurality of X heads 49 (here, seven) and constitutes the so-called multilens (i.e., seven-lens) X linear encoder 14B.

The head unit 47D uses the X heads 49 and the X scale 29 of the scale member T2 to measure the position of the substrate stage 1 in the X axial directions. The head unit 47D comprises a plurality of X heads 49 (here, eleven) and constitutes the so-called multilens (i.e., eleven-lens) X linear encoder 14D. In the head unit 47B, the spacing between adjacent X heads 49 (i.e., between the measurement lights of adjacent X heads 49) in the Y axial directions is smaller than the widths of the X scales 28, 29 in the Y axial directions (i.e., the length of each of the diffraction gratings RG). Likewise, in the head unit 47D, the spacing between adjacent X heads 49 (i.e., between the measurement lights of adjacent X heads 49) in the Y axial directions is smaller than the widths of the X scales 28, 29 in the Y axial directions (i.e., the length of each of the diffraction gratings RG).

In addition, the encoder system 14 comprises the Y linear encoder 14E, which comprises a Y head 48A disposed on the +X side of the secondary alignment system 15Ba, and the Y linear encoder 14F, which comprises a Y head 48B disposed on the −X side of the secondary alignment system 15Bd. The Y head 48A and the Y head 48B are capable of opposing the scale member T2.

Both of the Y heads 48A, 48B are disposed along a straight line that passes through the center of detection of the primary alignment system 15A and is parallel to the X axis. The Y head 48A and the Y head 48B are disposed substantially symmetrically with respect to the center of detection of the primary alignment system 15A. The spacing between the Y head 48A and the Y head 48B is substantially equal to that between the two reference gratings 45 of the fiducial member 44.

As shown in FIG. 7, when the center of the substrate P held by the substrate stage 1 is disposed along the straight line LV, the Y head 48A opposes the Y scale 27, and the Y head 48B opposes the Y scale 26. The encoder system 14 is capable of measuring the position of the substrate stage 1 in the Y axial and θZ directions using the Y heads 48A, 48B.

In addition, in the present embodiment, the two reference gratings 45 of the fiducial member 44 and the Y heads 48A, 48B are opposed, and by measuring the reference gratings 45 the Y heads 48A, 48B are capable of measuring the position of the fiducial member 44 in the Y axial directions.

The measurement values of the six linear encoders 14A-14F discussed above are output to the control apparatus 9. The control apparatus 9 controls the position of the substrate stage 1 within the XY plane based on the measurement values of the linear encoders 14A-14D and the position of the fiducial member 44 in the θZ directions based on the measurement values of the linear encoders 14E, 14F.

In the present embodiment, each of the linear encoders 14A-14F is supported by the frame member that supports the projection optical system PL. Each of the linear encoders 14A-14F hangs down from the frame member via a support member. Each of the linear encoders 14A-14F is disposed above the substrate stage 1 and the measurement stage 2.

Furthermore, in the exposure apparatus EX of the present embodiment, deformation measuring apparatuses 50Y, which are configured similarly to the deformation measuring apparatus 50 discussed above, are provided between the Y heads 48 of the head units 47A, 47C. The deformation measuring apparatuses 50Y are oriented such that their measurement directions are in the Y directions and are installed in each of the head units 47A, 47C.

Similarly, deformation measuring apparatuses 50X, which are configured similarly to the deformation measuring apparatus 50 discussed above, are provided between the X heads 49 of the head units 47B, 47D. The deformation measuring apparatuses 50X are oriented such that their measurement directions are in the X directions and are installed in each of the head units 47B, 47D.

The measurement results of these deformation measuring apparatuses 50X, 50Y are output to the control apparatus 9 (i.e., the correcting apparatus).

In the present embodiment, the encoder system 14 measures the position of the substrate stage 1 at least while the exposure operation is being performed on the substrate P. The control apparatus 9 uses the encoder system 14 and the scale member T2 to measure the position of the substrate stage 1 within the XY plane and exposes the substrate P.

While controlling the position of the substrate stage 1 within the XY plane based on the measurement values of the encoder system 14, the control apparatus 9 sequentially exposes a plurality of shot regions SH on the substrate P. In addition, while adjusting the positional relationship between the image plane of the projection optical system PL and the front surface of the substrate P based on the approximation plane of the substrate P derived prior to the performance of the exposure operation on the substrate P, the control apparatus 9 exposes the substrate P.

The exposure apparatus EX of the present embodiment is a scanning type exposure apparatus (i.e., a so-called scanning stepper) that projects the image of the pattern of the mask M to the substrate P while synchronously moving the mask M and the substrate P in prescribed scanning directions. In the present embodiment, the scanning directions (i.e., the synchronous movement directions) of both the substrate P and the mask M are oriented in the Y axial directions. The exposure apparatus EX moves a given shot region SH on the substrate P in the Y axial directions with respect to the projection area PR of the projection optical system PL and radiates the exposure light EL to the substrate P through the projection optical system PL and the liquid LQ while moving the mask M in the Y axial directions with respect to the illumination area IR of the illumination system IL synchronized to the movement of the substrate P in the Y axial directions, thereby exposing the substrate P.

At this time, the control apparatus 9 stores the measurement results of the deformation measuring apparatuses 50X, 50Y, which performed their measurements prior to the exposure (i.e., during alignment and the like); furthermore, when fluctuations arise in the measurement results of the deformation measuring apparatuses 50X, 50Y during an exposure operation, the control apparatus 9 judges that a deformation corresponding to the differential between the stored measurement results and the measurement results during the exposure operation has arisen in the head units 47B, 47D corresponding to relevant deformation measuring apparatus, and compensates the measurement results produced by the Y heads 48 and X heads 49 adjacent to the relevant deformation measuring apparatuses 50X, 50Y for that amount of deformation.

In the embodiment, the deformation measuring apparatus measures the deformation in the head unit; however, no limitation is imposed. Measuring the deformation in the head unit can be replaced with directly measuring the deformation in the encoder head. The deformation in the head unit would affects the measurement value for the X head or the Y head installed at the head unit. As a result, it can be said that the measurement of the deformation in the head unit is substantially equal to the measurement of the deformation of the encoder head in a broad sense.

Thus, in the present embodiment, a minute amount of deformation arising in the head units 47A-47D can be measured easily in a specific direction (i.e., in every measurement direction). Consequently, in the present embodiment, the control apparatus corrects the positions of the mask M and the substrate P based on the measurement results of these deformation measuring apparatuses 50X, 50Y and the like, which makes it possible to correct the position at which the substrate P is exposed with the pattern formed in the mask M (i.e., to correct the position in the X and Y directions and the focus direction) and thereby to increase how accurately the pattern is transferred.

The above text explained the embodiments according to the present invention, referencing the attached drawings, but of course the present invention is not limited to these embodiments. Each of the constituent members, shapes, and combinations described in the embodiments discussed above are merely exemplary, and it is understood that variations and modifications based on, for example, design requirements may be effected without departing from the spirit and scope of the invention.

For example, in the abovementioned third embodiment, the second slit parts S2 are rectangular in a plan view, but the present invention is not limited thereto; for example, they may be circular, elliptical, or some other shape in a plan view.

In addition, the abovementioned embodiments are configured such that the slit parts S and the second slit parts S2 adjoin the support part 53 (i.e., the piezoelectric device 52), but the present invention is not limited thereto; for example, a configuration may be adopted wherein they are spaced apart. In addition, the slit parts S do not necessarily have to be made long enough to make contact with the projections 54; for example, the slit parts S may be spaced apart from the projections 54. In such a case, it would be preferable to form the slit parts S such that they are longer than the sides of the piezoelectric device 52 (i.e., the support part 53) in the Y directions.

In addition, the abovementioned embodiments explained a configuration wherein the deformation measuring apparatuses are provided to the encoder system 14 of the exposure apparatus EX, but the present invention is not limited thereto; for example, a configuration may be adopted wherein the deformation measuring apparatuses are provided to a body that supports some other measuring apparatus (e.g., the interferometer system 12, the detection system 13, or the alignment system 15) or structural body (e.g., the illumination system IL, the mask stage 3, or the projection optical system PL). In such a case, it would be possible to easily measure, in every desired direction, a minute amount of deformation in the body, and to use the results thereof to correct the exposure position in accordance with the various structural calculations (e.g., the intensity calculation) and the amount of deformation.

In the embodiment, the deformation measuring apparatus measures the strain derived in the measurement target member; however, no limitation is imposed. Alternatively, the other value than a strain can be measured to obtain amount of deformation. As a strain indicator, a mechanical type, a type for using change of electric resistance, or the like can be applied. Alternatively, a configuration that detects a magnetic strain and the like can be applied.

Alternatively, in the encoder system 14, the scale member T2 and the head unit (47A-47D) can be interchanged in positional relationship so that the head unit is disposed on the substrate stage 1 and the scale member T2 is disposed facing them. In this case, the scale member T2 can be a plate member so as to face an entire moving area of the substrate stage 1 on the guide surface 6. In addition, a deformation measuring apparatus can be provided on the plate member (the scale member T2) for measuring amount of the deformation and to compensate the measurement result. The encoder system having such configuration can be found for example in US 2008/0240501. Alternatively, a deformation measuring apparatus can be provided at the substrate stage 1 side for measuring amount of deformation of the head unit that is attached to the substrate stage 1. In a case where such configuration is applied, the scale plate can be arranged in and divided into a plurality of parts. In the case, for example, an exposure area, where the substrate stage moves when the exposure process is executed, and a measurement area, where the measurement stage and the substrate stage move when the measuring process is executed, are set. Then, for a measurement in the exposure area, it can be divided into and arranged in four pieces centering around the projection optical system PL, and, for a measurement in the measurement area, it can be divided into and arranged in four pieces centering around the alignment system.

The scale plate can be supported via a configuration so that the deformation of a member supporting (connects) the scale plate has limited influence on the scale plate. For example, it can be hung from the projection optical system PL or a member that supports the projection optical system PL. In the case, the deformation measuring apparatus can be located in a space that is formed on the rear surface of the scale plate (i.e., a surface (a second surface) that is opposite side of a surface (a first surface) facing the encoder head). The number of the installed deformation measuring apparatuses can be varied. A distribution of the deformation can be measured by an arrangement where a plurality of apparatuses are arranged per one piece of the scale plate. Alternatively, deformations of both the encoder head and the scale plate can be measured.

The deformation measuring apparatus can be provided on the encoder scale so that it can measure the deformation of the encoder scale that is provided at the substrate stage.

Alternatively, in the embodiment, for example, when an error dependent on the temperature under an output (power voltage) of the deformation measuring apparatus (piezoelectric device) 50 is observed, a configuration for removing this temperature error can be applied. In such configuration, for example, a temperature sensor or the like is provided adjacent to a deformation measuring apparatus. A compensation value is previously obtained based on a measurement result (temperature information) of the temperature sensor and on the temperature error of the deformation measuring apparatus and is previously stored in a memory and or the like. When the measurement of the deformation measuring apparatus is executed, the temperature information is obtained by the temperature sensor at substantially the same time. The measurement result of the deformation measuring apparatus is corrected based on the compensation value at the temperature. Thereby, a temperature-dependent component included in the output from the deformation measuring apparatus can be canceled. In this regard, the compensation method is not limited to this.

Furthermore, in the projection optical system PL in each of the embodiments discussed above, the optical path on the emergent side (i.e., the image plane side) of the last optical element is filled with the liquid, but it is also possible to adopt a projection optical system wherein the optical path on the incident side (i.e., the object plane side) of the last optical element is also filled with the liquid, as disclosed in U.S. Patent Application Publication No. 2005/0248856.

Furthermore, although the liquid LQ in each of the embodiments discussed above is water, it may be a liquid other than water. It is preferable to use as the liquid LQ a liquid that is transparent to the exposure light EL, has as high a refractive index as possible, and is stable with respect to the projection optical system or the photosensitive film that forms the front surface of the substrate. For example, it is also possible to use hydro-fluoro-ether (HFE), perfluorinated polyether (PFPE), Fomblin oil, cedar oil, or the like as the liquid LQ. In addition, a liquid that has a refractive index of approximately 1.6 to 1.8 may be used as the liquid LQ. Furthermore, the optical element (i.e., the last optical element or the like) of the projection optical system PL that contacts the liquid LQ may be formed from a material that has a refractive index higher than that of quartz or fluorite (e.g., 1.6 or higher). In addition, it is also possible to use various fluids, for example, a supercritical fluid, as the liquid LQ.

In addition, if, for example, F₂ laser light, which does not transmit through water, is used as the exposure light EL, then a fluid that can transmit the F₂ laser light can be used as the liquid LQ, for example, a fluorine based fluid such as perfluoropolyether (PFPE) or a fluorine based oil. In this case, portions that contact the liquid LQ are lyophilically treated by forming a thin film with, for example, a substance that has a molecular structure that contains fluorine or the like and has low polarity.

Furthermore, in each of the embodiments discussed above, the projection area PR wherein the illumination light EL is radiated through the projection optical system PL is an on-axis area that includes the optical axis AX within the visual field of the projection optical system PL; however, similar to the so-called inline type optical system—which has a single optical axis and part of which is provided with an optical system that has a plurality of reflecting surfaces and that forms an intermediate image at least once (i.e., a catoptric system or a catadioptric system) as disclosed in, for example, PCT International Publication No. WO 2004/107011—the exposure area may be an off-axis area that includes the optical axis AX.

In addition, in each of the embodiments discussed above, the illumination area IR and the projection area PR are rectangular, but the present invention is not limited thereto, and these areas may be, for example, shaped like an arc, a trapezoid, or a parallelogram.

Each of the embodiments discussed above explained an exemplary case of an exposure apparatus that comprises the projection optical system PL, but the present invention can be adapted to an exposure apparatus and an exposing method that do not use the projection optical system PL. Thus, even if the projection optical system PL is not used, the exposure light can be radiated to the substrate through optical members, such as lenses, and an immersion space can be formed between the substrate and those optical members.

Furthermore, each of the embodiments discussed above explained an exemplary case wherein the exposure apparatus EX is an immersion exposure apparatus, but it may be a dry exposure apparatus that exposes the substrate P without an intermediating liquid.

In addition, in each of the embodiments discussed above, the exposure apparatus EX may be an EUV exposure apparatus that exposes the substrate P using extreme ultraviolet (EUV) light in the soft X-ray region.

Furthermore, the substrate P in each of the embodiments discussed above is not limited to a semiconductor wafer for fabricating semiconductor devices, but can also be adapted to, for example, a glass substrate for display devices, a ceramic wafer for thin film magnetic heads, or the original plate of a mask or a reticle (i.e., synthetic quartz or a silicon wafer) used by an exposure apparatus.

The exposure apparatus EX can also be adapted to a step-and-scan type scanning exposure apparatus (i.e., a scanning stepper) that scans and exposes the pattern of the mask M by synchronously moving the mask M and the substrate P, as well as to a step-and-repeat type projection exposure apparatus (i.e., a stepper) that successively steps the substrate P and performs a full field exposure of the pattern of the mask M with the mask M and the substrate P in a stationary state. In a case wherein the exposure apparatus EX is a stepper, it is possible to control the position of a stage with high accuracy by using an encoder to measure the position of the stage that holds the substrate and thereby to prevent the generation of measurement error owing to air turbulences.

Furthermore, when performing an exposure with a step-and-repeat system, the projection optical system is used to transfer a reduced image of a first pattern to the substrate P in a state wherein the first pattern and the substrate P are substantially stationary, after which the projection optical system may be used to perform a full-field exposure of the substrate P, wherein a reduced image of a second pattern partially superposes the first pattern in a state wherein the second pattern and the substrate P are substantially stationary (i.e., as in a stitching type full-field exposure apparatus). In addition, the stitching type exposure apparatus can also be adapted to a step-and-stitch type exposure apparatus that successively steps the substrate P and transfers at least two patterns onto the substrate P such that they are partially superposed.

In addition, the present invention can also be adapted to, for example, an exposure apparatus that combines on a substrate the patterns of two masks through a projection optical system and double exposes, substantially simultaneously, a single shot region on the substrate using a single scanning exposure, as disclosed in, for example, U.S. Pat. No. 6,611,316. In addition, the present invention can also be adapted to, for example, a proximity type exposure apparatus and a mirror projection aligner.

In addition, the present invention can also be adapted to a twin stage type exposure apparatus, which comprises a plurality of substrate stages, as disclosed in, for example, U.S. Pat. Nos. 6,341,007, 6,400,441, 6,549,269, 6,590,634, 6,208,407, and 6,262,796.

In addition, the present invention can also be adapted to an exposure apparatus that comprises a plurality of substrate stages and measurement stages. In addition, the present invention can also be adapted to an exposure apparatus that has just one substrate stage.

The type of exposure apparatus is not limited to an exposure apparatus for fabricating semiconductor devices by exposing the substrate P with the pattern of a semiconductor device, but can also be widely adapted to exposure apparatuses for fabricating, for example, liquid crystal devices or displays and to exposure apparatuses for fabricating thin film magnetic heads, image capturing devices (CCDs), micromachines, MEMS devices, DNA chips, or reticles and masks.

In addition, in each of the embodiments discussed above, an ArF excimer laser may be used as a light source apparatus that generates ArF excimer laser light as the exposure light EL; however, as disclosed in, for example, U.S. Pat. No. 7,023,610, it is also possible to use a harmonic generation apparatus that outputs pulsed light with a wavelength of 193 nm and that comprises: an optical amplifier part, which has a solid state laser light source (such as a DFB semiconductor laser or a fiber laser), a fiber amplifier, and the like; and a wavelength converting part.

Furthermore, in each of the embodiments discussed above, an optically transmissive mask is used wherein a prescribed shielding pattern (or phase pattern or dimming pattern) is formed on an optically transmissive substrate; however, instead of such a mask, a variable pattern forming mask (also called an electronic mask, an active mask, or an image generator), wherein a transmissive pattern, a reflective pattern, or a light emitting pattern is formed based on electronic data of the pattern to be exposed, may be used as disclosed in, for example, U.S. Pat. No. 6,778,257. The variable pattern forming mask comprises a digital micromirror device (DMD), which is one kind of non-emissive type image display device (e.g., a spatial light modulator). In addition, the variable forming mask is not limited to a DMD, and a non-emissive type image display device, which is explained below, may be used instead. Here, the non-emissive type image display device is a device that spatially modulates the amplitude (i.e., the intensity), the phase, or the polarization state of the light that travels in a prescribed direction; furthermore, examples of a transmissive type spatial light modulator include a transmissive type liquid crystal display (LCD) as well as an electrochromic display (ECD). In addition, examples of a reflecting type spatial light modulator include a DMD, which was discussed above, as well as a reflecting mirror array, a reflecting type LCD, an electrophoretic display (EPD), electronic paper (or electronic ink), and a grating light valve.

In addition, instead of a variable pattern forming mask that comprises a non-emissive type image display device, a pattern forming apparatus that comprises a self luminous type image display device may be provided. In this case, an illumination system would not be necessary. Here, examples of a self luminous type image display device include a cathode ray tube (CRT), an inorganic electroluminescence display, an organic electroluminescence display (i.e., an organic light emitting diode (OLED)), an LED display, an LD display, a field emission display (FED), and a plasma display (i.e., a plasma display panel (PDP)). In addition, a solid state light source chip that has a plurality of light emitting points or that creates a plurality of light emitting points on a single substrate, a solid state light source chip array wherein a plurality of chips are arrayed, or the like may be used as the self luminous type image display device that constitutes the pattern forming apparatus, and the pattern may be formed by electrically controlling the solid state light source chip or chips. Furthermore, it does not matter whether the solid state light source device is inorganic or organic.

In addition, by forming interference fringes on the substrate P as disclosed in, for example, PCT International Publication No. WO2001/035168, the present invention can also be adapted to an exposure apparatus (i.e., a lithographic system) that exposes the substrate P with a line-and-space pattern.

As described above, the exposure apparatus of the above-described embodiments in the present application is manufactured by assembling various subsystems, including each constituent element, so that prescribed mechanical, electrical, and optical accuracies are maintained. To ensure these various accuracies, adjustments are performed before and after this assembly, including an adjustment to achieve optical accuracy for the various optical systems, an adjustment to achieve mechanical accuracy for the various mechanical systems, and an adjustment to achieve electrical accuracy for the various electrical systems. The process of assembling the exposure apparatus from the various subsystems includes, for example, the mechanical interconnection of the various subsystems, the wiring and connection of electrical circuits, and the piping and connection of the atmospheric pressure circuit. Naturally, prior to performing the process of assembling the exposure apparatus from these various subsystems, there are also the processes of assembling each individual subsystem. When the process of assembling the exposure apparatus from the various subsystems is complete, a comprehensive adjustment is performed to ensure the various accuracies of the exposure apparatus as a whole. Furthermore, it is preferable to manufacture the exposure apparatus in a clean room wherein, for example, the temperature and the cleanliness level are controlled.

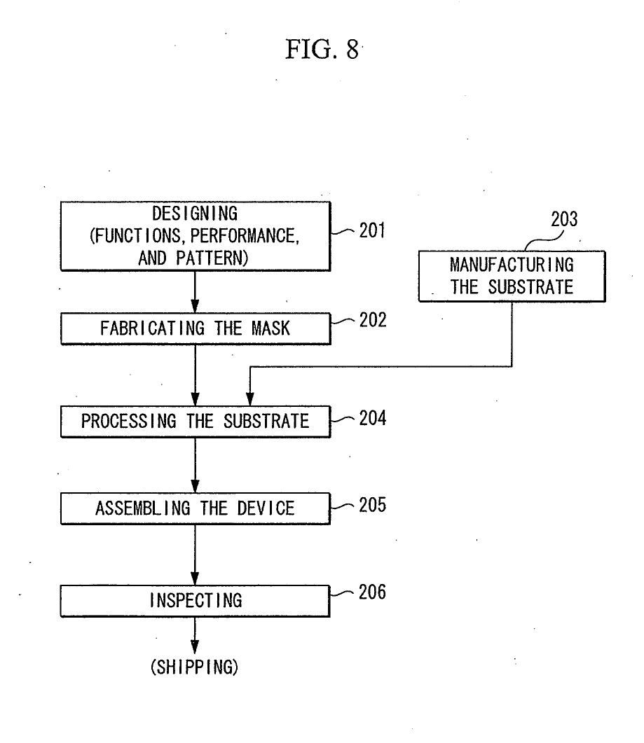

As shown in FIG. 8, a microdevice, such as a semiconductor device, is manufactured by: a step S10 that designs the functions and performance of the microdevice; a step S11 that fabricates a mask (i.e., a reticle) based on this designing step; a step S12 that manufactures a substrate (i.e., wafer), which is the base material of the device; a substrate (i.e., wafer) processing step S13 that comprises a substrate process (i.e., an exposure process) that includes, in accordance with the embodiments discussed above, exposing the substrate with the exposure light using the mask pattern and developing the exposed substrate; a device assembling step S14 (which includes fabrication processes such as dicing, bonding, and packaging processes); an inspecting step S15; and the like.

Furthermore, the features of each of the embodiments discussed above can be combined as appropriate. In addition, each disclosure of every documents and U.S. patent related to the exposure apparatus recited in each of the embodiments, modified examples, and the like discussed above is hereby incorporated by reference in its entirety.

What is claimed is:

1. A deformation measuring apparatus comprising:
a piezoelectric device provided to a base member; and
a regulating apparatus that regulates, of deformations of a measurement target transmitted via the base member to the piezoelectric device, a transmission of a deformation in a second direction, which intersect a first direction.

2. The deformation measuring apparatus according to claim 1, wherein
the regulating apparatus comprises first slit parts formed on the base member, the first slit parts extending in at least the first direction at both sides of the piezoelectric device in the second direction.

3. The deformation measuring apparatus according to claim 2, wherein
the regulating apparatus comprises second slit parts formed on the base member, the second slit parts being spaced apart in the second direction at both sides of the piezoelectric device in the first direction.

4. The deformation measuring apparatus according to claim 3, wherein
the second slit parts are connected to the first slit parts.

5. The deformation measuring apparatus according to claim 1, wherein
a projection, which extends in at least the first direction, is provided to the base member.

6. The deformation measuring apparatus according to claim 5, wherein
a plurality of the projections comprises a first projection part and a second projection part that are disposed spaced apart from each other by a gap; and
the regulating apparatus is disposed between the first projection part and the second projection part.

7. The deformation measuring apparatus according to claim 5, wherein
the projection has a joining surface at which it joins with the measurement target.

8. An exposure apparatus that exposes a substrate with a pattern, comprising:
a deformation measuring apparatus according to claim 1.

9. The exposure apparatus according to claim 8, further comprising:
a correcting apparatus that corrects information related to the exposure position of the pattern based on the measurement result of the deformation measuring apparatus.

10. The exposure apparatus according to claim 9, further comprising:
a position measuring apparatus that measures a position of the substrate,
wherein the deformation measuring apparatus is provided to the position measuring apparatus.

11. The exposure apparatus according to claim 9, wherein
the deformation measuring apparatus is provided to the substrate.

12. A jig for the deformation measuring apparatus comprising:
a base member that supports a piezoelectric device with a support part; and
a regulating apparatus that regulates, of deformations of a measurement target transmitted via the base member to the support part, a transmission of deformation in a second direction, which intersects a first direction.

13. The jig for the deformation measuring apparatus according to claim 12, wherein
the regulating apparatus comprises first slit parts formed on the base member, the first slit parts extending in at least the first direction at both sides of the piezoelectric device in the second direction.

14. The jig for the deformation measuring apparatus according to claim 13, wherein
the regulating apparatus comprises second slit parts formed on the base member, the second slit parts being spaced apart in the second direction at both sides of the piezoelectric device in the first direction.

15. The jig for the deformation measuring apparatus according to claim 14, wherein
the second slit parts are connected to the first slit parts.

16. The jig for the deformation measuring apparatus according to claim 12, wherein
a projection, which extends in at least the first direction, is provided to the base member.

17. The jig for the deformation measuring apparatus according to claim 16, wherein
a plurality of the projections comprises a first projection part and a second projection part that are disposed spaced apart by a gap; and
the regulating apparatus is disposed between the first projection part and the second projection part.

18. A deformation measuring apparatus, which uses a piezoelectric device to measure deformation that arises in a measurement target, comprising:
a base member, which connects with the measurement target;
a support member, which supports the piezoelectric device; and
a flexure member, which connects the base member and the support member;
wherein
the flexure member creates, regarding deformation of the measurement target transmitted via the base member to the support member, a differential between a degree of transmission of deformation in a first direction and a degree of transmission of deformation in a second direction that intersects the first direction.

19. A jig for the deformation measuring apparatus that uses a piezoelectric device to measure deformation that arises in a measurement target, comprising:
a base member, which contacts the measurement target;
a support member, which supports the piezoelectric device; and
a flexure member, which connects the base member and the support member;
wherein,
the flexure member creates, regarding deformation of the measurement target transmitted via the base member to the support member, a differential between a degree of transmission of deformation in a first direction and a degree of transmission of deformation in a second direction that intersects the first direction.

20. An exposure apparatus that forms a predetermined pattern on a substrate supported by a mover, the apparatus comprising:
an encoder apparatus that obtains information about a position of the mover; and
a deformation measuring apparatus that is provided at least one of an encoder head and an encoder scale and that obtains information about a deformation of the one, the encoder apparatus comprising the encoder head and the encoder scale.

21. The exposure apparatus according to claim 20, wherein the encoder scale is provided at the mover, and wherein the deformation measuring apparatus obtains information about a deformation in the encoder head.

22. The exposure apparatus according to claim 20, wherein the encoder head is provided at the mover, and wherein the deformation measuring apparatus obtains information about a deformation in the encoder scale.

23. The exposure apparatus according to claim 22, further comprising
an optical member that irradiates the substrate with an exposure light; and
a support member that supports the optical member,
wherein the encoder scale is supported by the optical member or the support member.

24. The exposure apparatus according to claim 23, wherein the encoder scale is hung from and supported by the optical member or the support member.

25. The exposure apparatus according to claim 24, wherein the encoder scale has a first face that faces the encoder head and a second face that is opposite to the second face, and wherein the deformation measuring apparatus is provided at the second surface.

26. The exposure apparatus according to claim 20, wherein the encoder scale is divided into a plurality of parts, and wherein the deformation measuring apparatus is provided at each of the divided parts of the encoder scale.

27. The exposure apparatus according to claim 20, wherein the deformation measuring apparatus measures a strain of the encoder head or the encoder scale.

28. The exposure apparatus according to claim 20, wherein the deformation measuring apparatus obtains information about a deformation under no influence of temperature.

29. The exposure apparatus according to claim 28, wherein the deformation measuring apparatus has a temperature sensor and obtains information about a deformation by using a measurement result of the temperature sensor.

30. A device fabricating method that uses an exposure apparatus according to claim 20.

31. The deformation measuring apparatus according to claim 1, wherein information about a deformation of the measurement target is obtained under no influence of a deformation by temperature in the measurement target.

32. The deformation measuring apparatus according to claim 31, further comprising a temperature sensor that obtains information about a temperature of the measurement target, wherein information about a deformation is obtained by use of a measurement result of the temperature sensor.

33. A position measuring method of obtaining information about a position of a mover that supports a substrate onto which a predetermined pattern is formed in an exposure apparatus, the method comprising:
obtaining information about a position of the mover by an encoder apparatus; and
obtaining information about a deformation of at least one of an encoder head and an encoder scale, the encoder apparatus comprising the encoder head and the encoder scale.
